(19) United States
(12) Patent Application Publication
(10) Pub. No.: US 2025/0220822 A1
(43) Pub. Date: Jul. 3, 2025

(54) COVERLAY FILM, PRINTED WIRING BOARD, METHOD FOR MANUFACTURING COVERLAY FILM, AND METHOD FOR MANUFACTURING PRINTED WIRING BOARD

(71) Applicant: SUMITOMO ELECTRIC PRINTED CIRCUITS, INC., Shiga (JP)

(72) Inventor: Takuma HITOTSUMATSU, Shiga (JP)

(73) Assignee: SUMITOMO ELECTRIC PRINTED CIRCUITS, INC., Shiga (JP)

(21) Appl. No.: 18/850,596

(22) PCT Filed: Mar. 23, 2023
(86) PCT No.: PCT/JP2023/011435

§ 371 Date: Sep. 25, 2024

(30) Foreign Application Priority Data
Mar. 31, 2022 (JP) 2022-059505

(51) Int. Cl. H05K 3/28; H05K 1/03

(52) U.S. Cl. CPC H05K 3/28; H05K 1/0393; H05K 2203/0264; H05K 2203/061; H05K 2203/1453

(57) ABSTRACT

A coverlay film includes an insulating film having a first main surface and a second main surface as a surface opposite to the first main surface, an adhesive layer disposed on the first main surface and formed from an uncured adhesive, and a separator disposed on the adhesive layer. The insulating film has a thickness of more than or equal to 2 μm and less than or equal to 15 μm. The adhesive layer has a thickness of more than or equal to 10 μm and less than or equal to 50 μm.

### TECHNICAL FIELD

The present disclosure relates to a coverlay film, a printed wiring board, a method for manufacturing a coverlay film, and a method for manufacturing a printed wiring board. The present application claims priority based on Japanese Patent Application No. 2022-059505 filed on Mar. 31, 2022. The entire contents described in the Japanese patent application are incorporated herein by reference.

### BACKGROUND ART

As described for example in Japanese Patent Laying-Open No. 2019-116619 (PTL 1), a coverlay film has an insulating film and an adhesive layer. The insulating film is formed from a material having electric insulation and flexibility. The adhesive layer is disposed on a main surface of the insulating film.

### CITATION LIST

### Patent Literature

PTL 1: Japanese Patent Laying-Open No. 2019-116619

### SUMMARY OF INVENTION

A coverlay film of the present disclosure includes an insulating film having a first main surface and a second main surface as a surface opposite to the first main surface, an adhesive layer disposed on the first main surface and formed from an uncured adhesive, and a separator disposed on the adhesive layer. The insulating film has a thickness of more than or equal to 2 μm and less than or equal to 15 μm. The adhesive layer has a thickness of more than or equal to 10 μm and less than or equal to 50 μm.

### BRIEF DESCRIPTION OF DRAWINGS

FIG. 1 is a cross sectional view of a coverlay film 100.

FIG. 2 is a manufacturing process diagram for coverlay film 100.

FIG. 3 is a cross sectional view of a printed wiring board 200.

FIG. 4 is a manufacturing process diagram for printed wiring board 200.

### DETAILED DESCRIPTION

### Problem to be Solved by the Present Disclosure

A coverlay film is attached to a printed wiring board. More specifically, the printed wiring board has a base film, and a conductive pattern disposed on a main surface of the base film. The coverlay film is disposed on the main surface of the base film such that an adhesive layer covers the conductive pattern.

In a case where the adhesive layer has a small thickness, when the distance between adjacent portions of the conductive pattern is small, it is difficult to fill a space between the adjacent portions of the conductive pattern with the adhesive layer. In a case where the insulating film has a large thickness, it is difficult to thin the printed wiring board having the coverlay film attached thereto.

The present disclosure has been made in view of the problem of the conventional technique as described above. More specifically, the present disclosure provides a coverlay film that can improve filling properties of an adhesive layer into a space between adjacent portions of a conductive pattern, and can thin a printed wiring board.

### Advantageous Effect of the Present Disclosure

According to the coverlay film of the present disclosure, it is possible to improve filling properties of an adhesive layer into a space between adjacent portions of a conductive pattern, and to thin a printed wiring board.

### Description of Embodiments of the Present Disclosure

First, embodiments of the present disclosure will be described in list form.

(1) A coverlay film in accordance with an embodiment includes an insulating film having a first main surface and a second main surface as a surface opposite to the first main surface, an adhesive layer disposed on the first main surface and formed from an uncured adhesive, and a separator disposed on the adhesive layer. The insulating film has a thickness of more than or equal to 2 μm and less than or equal to 15 μm. The adhesive layer has a thickness of more than or equal to 10 μm and less than or equal to 50 μm.

According to the coverlay film in (1), it is possible to improve filling properties of the adhesive layer into a space between adjacent portions of a conductive pattern, and to thin a printed wiring board.

(2) The coverlay film in (1) may further include a protective film. The protective film may be disposed on the second main surface.

According to the coverlay film in (2), occurrence of a damage to the insulating film can be suppressed. Further, according to the coverlay film in (2), handling properties of the coverlay film can be improved.

(3) In the coverlay film in (2), a peel strength of the protective film with respect to the insulating film may be greater than a peel strength of the separator with respect to the adhesive layer.

According to the coverlay film in (3), the separator can be peeled off from the adhesive layer without peeling off the protective film from the insulating film.

(4) In the coverlay film in (1) to (3), the thickness of the adhesive layer may be larger than the thickness of the insulating film.

(5) In the coverlay film in (1) to (4), the insulating film may have a thickness of more than or equal to 2 μm and less than or equal to 13 μm. The adhesive layer may have a thickness of more than or equal to 20 μm and less than or equal to 50 μm.

(6) In the coverlay film in (1) to (5), the insulating film may be formed from polyimide or a liquid crystal polymer.

(7) A printed wiring board in accordance with an embodiment includes a base film having a third main surface, a conductive pattern disposed on the third main surface, and the coverlay film in (1) to (6). The separator is peeled off in the coverlay film. The coverlay film is disposed on the third main surface such that the adhesive layer covers the conductive pattern. The adhesive is cured.

According to the printed wiring board in (7), it is possible to improve filling properties of the adhesive layer into a space between adjacent portions of the conductive pattern, and to thin the printed wiring board.

(8) A method for manufacturing a coverlay film in accordance with an embodiment includes: preparing an insulating film which has a first main surface and a second main surface as a surface opposite to the first main surface, and in which a protective film is disposed on the second main surface; forming an adhesive layer from an uncured adhesive on the first main surface; and disposing a separator on the adhesive layer. The insulating film has a thickness of more than or equal to 2 μm and less than or equal to 15 μm. The adhesive layer has a thickness of more than or equal to 10 μm and less than or equal to 50 μm.

According to the method for manufacturing the coverlay film in (8), the coverlay film can be suppressed from falling during a manufacturing process.

(9) The method for manufacturing the coverlay film in (8) may further include peeling off the protective film from the insulating film.

(10) A method for manufacturing a printed wiring board in accordance with an embodiment includes: preparing a coverlay film having an insulating film including a first main surface and a second main surface as a surface opposite to the first main surface, an adhesive layer disposed on the first main surface and formed from an uncured adhesive, a protective film disposed on the second main surface, and a separator disposed on the adhesive layer; peeling off the separator from the adhesive layer; preparing a base film which has a third main surface and in which a conductive pattern is disposed on the third main surface; disposing the coverlay film on the third main surface such that the adhesive layer covers the conductive pattern, and curing the adhesive; and peeling off the protective film from the insulating film.

According to the method for manufacturing the printed wiring board in (10), it is possible to improve filling properties of the adhesive layer into a space between adjacent portions of the conductive pattern, and to thin the printed wiring board.

(11) In the method for manufacturing the printed wiring board in (10), the protective film may be peeled off after the coverlay film is disposed on the third main surface.

According to the method for manufacturing the printed wiring board in (11), handling properties of the coverlay film can be improved.

### Details of Embodiments of the Present Disclosure

Details of the embodiments of the present disclosure will be described with reference to the drawings. In the drawings below, identical or corresponding parts will be designated by the same reference numerals, and overlapping description will not be repeated.

Coverlay Film in Accordance with Embodiment

A coverlay film in accordance with an embodiment will be described. The coverlay film in accordance with the embodiment is referred to as a coverlay film 100.

### Configuration of Coverlay Film 100

In the following, a configuration of coverlay film 100 will be described.

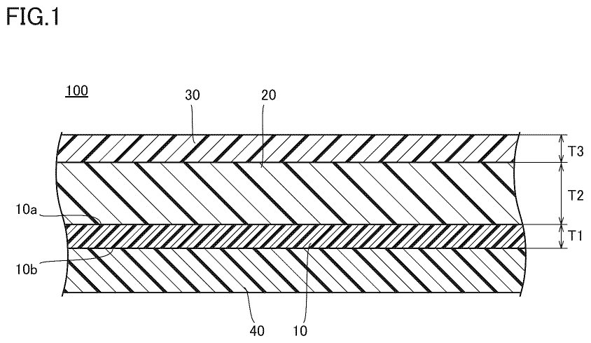

FIG. 1 is a cross sectional view of coverlay film 100. As shown in FIG. 1, coverlay film 100 has an insulating film 10, an adhesive layer 20, and a separator 30. Coverlay film 100 may have a protective film 40. However, coverlay film 100 may not have protective film 40.

Insulating film 10 has a first main surface 10a and a second main surface 10b. First main surface 10a and second main surface 10b are end surfaces in a thickness direction of insulating film 10. Second main surface 10b is a surface opposite to first main surface 10a. Insulating film 10 is formed from an electrical insulating material having flexibility. Insulating film 10 is formed from polyimide, for example. Insulating film 10 may be formed from a liquid crystal polymer. However, the material constituting insulating film 10 is not limited thereto.

Adhesive layer 20 is disposed on first main surface 10a. Adhesive layer 20 is formed from an uncured adhesive. The adhesive is an epoxy-based adhesive, for example. However, the adhesive is not limited thereto.

A thickness of insulating film 10 and a thickness of adhesive layer 20 are referred to as a thickness T1 and a thickness T2, respectively. Thickness T1 is more than or equal to 2 μm and less than or equal to 15 μm. Thickness T2 is more than or equal to 10 μm and less than or equal to 50 μm. Preferably, thickness T2 is larger than thickness T1. Preferably, thickness T1 is more than or equal to 2 μm and less than or equal to 13 μm. Preferably, thickness T2 is more than or equal to 20 μm and less than or equal to 50 μm. It should be noted that thickness T2 is the thickness of adhesive layer 20 in a state dried in an adhesive layer forming step S2 described later.

Separator 30 is disposed on adhesive layer 20. Separator 30 is formed from a base material subjected to mold release treatment. The base material is formed from a resin material such as polyethylene terephthalate, polypropylene, or polyethylene, or from paper, for example. However, the material constituting the base material is not limited thereto. A thickness of separator 30 is referred to as a thickness T3. Thickness T3 is more than or equal to 10 μm and less than or equal to 150 μm, for example.

Protective film 40 is disposed on second main surface 10b. Protective film 40 is formed from a resin material such as polyethylene terephthalate, for example. However, the material constituting protective film 40 is not limited thereto. Although not shown, a layer of an adhesive for attaching protective film 40 to second surface 10b may be interposed between second surface 10b and protective films 40.

A peel strength of protective film 40 with respect to insulating film 10 is greater than a peel strength of separator 30 with respect to adhesive layer 20. Thereby, separator 30 can be peeled off from adhesive layer 20 without peeling off separator 30 from insulating film 10. It should be noted that the peel strength of protective film 40 with respect to insulating film 10 and the peel strength of separator 30 with respect to adhesive layer 20 are measured according to JIS Z 0237:2009.

### Method for Manufacturing Coverlay Film 100

In the following, a method for manufacturing coverlay film 100 will be described.

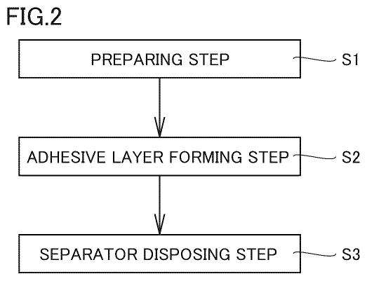

FIG. 2 is a manufacturing process diagram for coverlay film 100. The method for manufacturing coverlay film 100 has a preparing step S1, adhesive layer forming step S2, and a separator disposing step S3, as shown in FIG. 2. Adhesive layer forming step S2 is performed after preparing step S1, and separator disposing step S3 is performed after adhesive layer forming step S2.

In preparing step S1, insulating film 10 is prepared. In insulating film 10 prepared in preparing step S1, protective film 40 is disposed on second main surface 10b.

In adhesive layer forming step S2, adhesive layer 20 is formed on first main surface 10a. In adhesive layer forming step S2, firstly, an uncured adhesive is applied on first main surface 10a. Secondly, the uncured adhesive applied on first main surface 10a is dried. The uncured adhesive applied on first main surface 10a is dried by blowing hot air, for example.

In separator disposing step S3, separator 30 is disposed on adhesive layer 20. Thereby, coverlay film 100 with a structure shown in FIG. 1 is manufactured. It should be noted that protective film 40 may be peeled off from insulating film 10 after separator disposing step S3 is performed.

Printed Wiring Board in Accordance with Embodiment

A printed wiring board in accordance with an embodiment will be described. The printed wiring board in accordance with the embodiment is referred to as a printed wiring board 200.

### Configuration of Printed Wiring Board 200

In the following, a configuration of printed wiring board 200 will be described.

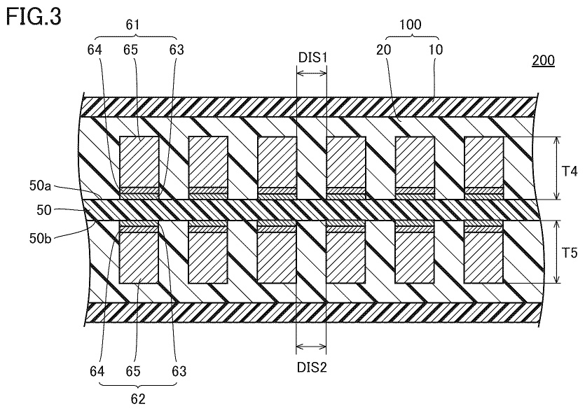

FIG. 3 is a cross sectional view of printed wiring board 200. As shown in FIG. 3, printed wiring board 200 has a base film 50, a conductive pattern 61 and a conductive pattern 62, and coverlay films 100.

Base film 50 has a third main surface 50a and a fourth main surface 50b. Third main surface 50a and fourth main surface 50b are end surfaces in a thickness direction of base film 50. Fourth main surface 50b is a surface opposite to third main surface 50a. Base film 50 is formed from an electrical insulating material having flexibility. Base film 50 is formed from polyimide, for example. Base film 50 may be formed from a liquid crystal polymer. However, the material constituting base film 50 is not limited thereto.

Conductive pattern 61 and conductive pattern 62 are disposed on third main surface 50a and fourth main surface 50b, respectively. Conductive pattern 61 and conductive pattern 62 are formed by a semiadditive method, for example. More specifically, each of conductive pattern 61 and conductive pattern 62 has a seed layer 63, an electroless plating layer 64, and an electrolytic plating layer 65. However, conductive pattern 61 and conductive pattern 62 may be formed by a subtractive method.

A thickness of conductive pattern 61 and a thickness of conductive pattern 62 are referred to as a thickness T4 and a thickness T5, respectively. Thickness T4 and thickness T5 are more than or equal to 10 μm and less than or equal to 60 μm, for example. A distance between two adjacent portions of conductive pattern 61 is referred to as a distance DIS1. A distance between two adjacent portions of conductive pattern 62 is referred to as a distance DIS2. Distance DIS1 and distance DIS2 are more than or equal to 5 μm and less than or equal to 50 μm, for example.

Seed layer 63 is disposed on a main surface (third main surface 50a, fourth main surface 50b) of base film 50. Seed layer 63 is a sputtered layer (a layer formed by sputtering), for example. Seed layer 63 is constituted by a layer of a nickel-chromium alloy disposed on a main surface (third main surface 50a, fourth main surface 50b) of base film 50, and a layer of copper disposed on the layer of the nickel-chromium alloy, for example.

Electroless plating layer 64 is disposed on seed layer 63. Electroless plating layer 64 is a layer formed by electroless plating. Electroless plating layer 64 is formed from copper, for example. Electrolytic plating layer 65 is disposed on electroless plating layer 64. Electrolytic plating layer 65 is a layer formed by electrolytic plating. Electrolytic plating layer 65 is formed from copper, for example.

Coverlay film 100 is disposed on third main surface 50a such that adhesive layer 20 covers conductive pattern 61. Coverlay film 100 is also disposed on fourth main surface 50b such that adhesive layer 20 covers conductive pattern 62. In coverlay film 100 in a state where it is attached to base film 50, the adhesive constituting adhesive layer 20 is cured, and protective film 40 is peeled off from insulating film 10.

Although the above description describes an example where conductive pattern 61 and conductive pattern 62 are disposed on third main surface 50a and fourth main surface 50b, respectively, printed wiring board 200 may not have either one of conductive pattern 61 and conductive pattern 62. It should be noted that, when printed wiring board 200 does not have conductive pattern 61, coverlay film 100 is not attached to third main surface 50a, and when printed wiring board 200 does not have conductive pattern 62, coverlay film 100 is not attached to fourth main surface 50b.

### Method for Manufacturing Printed Wiring Board 200

In the following, a method for manufacturing printed wiring board 200 will be described.

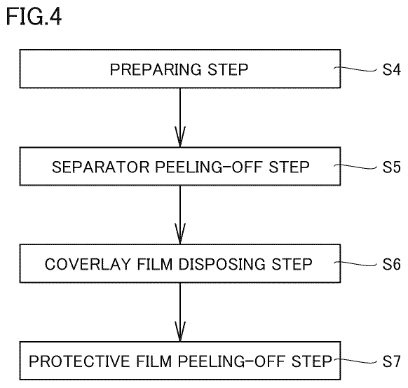

FIG. 4 is a manufacturing process diagram for printed wiring board 200. As shown in FIG. 4, the method for manufacturing printed wiring board 200 has a preparing step S4, a separator peeling-off step S5, a coverlay film disposing step S6, and a protective film peeling-off step S7. Separator peeling-off step S5 is performed after preparing step S4. Coverlay film disposing step S6 is performed after separator peeling-off step S5. Protective film peeling-off step S7 is performed after coverlay film disposing step S6.

In preparing step S4, base film 50 and coverlay films 100 are prepared. In base film 50 prepared in preparing step S4, conductive pattern 61 and conductive pattern 62 are disposed on third main surface 50a and fourth main surface 50b, respectively.

In separator peeling-off step S5, in each coverlay film 100 prepared in preparing step S4, separator 30 is peeled off from adhesive layer 20.

In coverlay film disposing step S6, coverlay film 100 is disposed on third main surface 50a such that adhesive layer 20 covers conductive pattern 61, and coverlay film 100 is disposed on fourth main surface 50b such that adhesive layer 20 covers conductive pattern 62.

In coverlay film disposing step S6, firstly, coverlay film 100 is disposed on third main surface 50a such that adhesive layer 20 covers conductive pattern 61, and coverlay film 100 is disposed on fourth main surface 50b such that adhesive layer 20 covers conductive pattern 62. Secondly, base film 50 having coverlay films 100 attached thereto is heated and pressurized. Thereby, the adhesive constituting adhesive layer 20 is cured, and coverlay films 100 are attached to third main surface 50a and fourth main surface 50b.

In protective film peeling-off step S7, protective film 40 is peeled off from insulating film 10. Thereby, printed wiring board 200 with a structure shown in FIG. 3 is manufactured. It should be noted that, when protective film 40 is peeled off from insulating film 10 after separator disposing step S3 is performed, protective film peeling-off step S7 may not be performed.

### Effect

In the following, the effect of coverlay film 100 and printed wiring board 200 will be described.

In a case where thickness T1 is large, printed wiring board 200 also has a large thickness, and it is not possible to thin printed wiring board 200. In a case where thickness T2 is small, when distance DIS1 (distance DIS2) is small, it is not possible to fill a space between the adjacent portions of conductive pattern 61 (conductive pattern 62) with adhesive layer 20.

However, in coverlay film 100, thickness T1 is small (specifically, more than or equal to 2 μm and less than or equal to 15 μm), and thickness T2 is large (specifically, more than or equal to 10 μm and less than or equal to 50 μm). Therefore, according to coverlay film 100, it is possible to improve filling properties of adhesive layer 20 into a space between the adjacent portions of conductive pattern 61 (conductive pattern 62), and to thin printed wiring board 200.

When thickness T1 is small and thickness T2 is large, rigidity of coverlay film 100 is decreased, and handling thereof may be difficult. In coverlay film 100, since protective film 40 is disposed on second main surface 10b, rigidity of coverlay film 100 is increased, and thus handling properties of coverlay film 100 can be improved.

Further, since protective film 40 is disposed on second main surface 10b, occurrence of a damage (for example, surface scratch, dent, split, burr, or the like) to insulating film 10 can be suppressed.

When the peel strength of protective film 40 with respect to insulating film 10 is greater than the peel strength of separator 30 with respect to adhesive layer 20, separator 30 can be peeled off from adhesive layer 20 without peeling off protective film 40 from insulating film 10.

When thickness T1 is small and thickness T2 is large, coverlay film 100 may fall when adhesive layer 20 is dried by hot air. However, since protective film 40 is disposed on second main surface 10b, coverlay film 100 is suppressed from falling when adhesive layer 20 is dried.

In printed wiring board 200, thickness T1 is small (more specifically, more than or equal to 2 μm and less than or equal to 15 μm), and thickness T2 is large (more specifically, more than or equal to 10 μm and less than or equal to 50 μm). Therefore, according to printed wiring board 200, it is possible to improve filling properties of adhesive layer 20 into a space between the adjacent portions of conductive pattern 61 (conductive pattern 62), and to thin printed wiring board 200.

It should be understood that the embodiments disclosed herein are illustrative and non-restrictive in every respect. The scope of the present invention is defined by the scope of the claims, rather than the embodiments described above, and is intended to include any modifications within the scope and meaning equivalent to the scope of the claims.

### REFERENCE SIGNS LIST

10: insulating film; 10a: first main surface; 10b: second main surface; 20: adhesive layer; 30: separator; 40: protective film; 50: base film; 50a: third main surface; 50b: fourth main surface; 61, 62: conductive pattern; 63: seed layer; 64: electroless plating layer; 65: electrolytic plating layer; 100: coverlay film; 200: printed wiring board; DIS1, DIS2: distance; S1: preparing step; S2: adhesive layer forming step; S3: separator disposing step; S4: preparing step; S5: separator peeling-off step; S6: coverlay film disposing step; S7: protective film peeling-off step; T1, T2, T3, T4, T5: thickness.

1. A coverlay film comprising:
an insulating film having a first main surface and a second main surface as a surface opposite to the first main surface;
an adhesive layer disposed on the first main surface and formed from an uncured adhesive; and
a separator disposed on the adhesive layer, wherein
the insulating film has a thickness of more than or equal to 2 μm and less than or equal to 15 μm, and
the adhesive layer has a thickness of more than or equal to 10 μm and less than or equal to 50 μm.

2. The coverlay film according to claim 1, further comprising a protective film, wherein
the protective film is disposed on the second main surface.

3. The coverlay film according to claim 2, wherein a peel strength of the protective film with respect to the insulating film is greater than a peel strength of the separator with respect to the adhesive layer.

4. The coverlay film according to claim 1, wherein the thickness of the adhesive layer is larger than the thickness of the insulating film.

5. The coverlay film according to claim 1, wherein
the insulating film has a thickness of more than or equal to 2 μm and less than or equal to 13 μm, and
the adhesive layer has a thickness of more than or equal to 20 μm and less than or equal to 50 μm.

6. The coverlay film according to claim 1, wherein the insulating film is formed from polyimide or a liquid crystal polymer.

7. A printed wiring board comprising:
a base film having a third main surface;
a conductive pattern disposed on the third main surface; and
the coverlay film according to claim 1, wherein
the separator is peeled off in the coverlay film,
the coverlay film is disposed on the third main surface such that the adhesive layer covers the conductive pattern, and
the adhesive is cured.

8. A method for manufacturing a coverlay film, the method comprising:
preparing an insulating film which has a first main surface and a second main surface as a surface opposite to the first main surface, and in which a protective film is disposed on the second main surface;
forming an adhesive layer from an uncured adhesive on the first main surface; and
disposing a separator on the adhesive layer, wherein
the insulating film has a thickness of more than or equal to 2 μm and less than or equal to 15 μm, and
the adhesive layer has a thickness of more than or equal to 10 μm and less than or equal to 50 μm.

9. The method for manufacturing the coverlay film according to claim 8, further comprising peeling off the protective film from the insulating film.

10. A method for manufacturing a printed wiring board, the method comprising:
preparing a coverlay film having an insulating film including a first main surface and a second main surface as a surface opposite to the first main surface, an adhesive layer disposed on the first main surface and formed from an uncured adhesive, a protective film disposed on the second main surface, and a separator disposed on the adhesive layer;
peeling off the separator from the adhesive layer;
preparing a base film which has a third main surface and in which a conductive pattern is disposed on the third main surface;
disposing the coverlay film on the third main surface such that the adhesive layer covers the conductive pattern, and curing the adhesive; and
peeling off the protective film from the insulating film.

11. The method for manufacturing the printed wiring board according to claim 10, wherein the protective film is peeled off after the coverlay film is disposed on the third main surface.
